(19) United States
(12) Patent Application Publication
(10) Pub. No.: US 2002/0155710 A1
(43) Pub. Date: Oct. 24, 2002

(54) HDD suspension and its manufacture

(76) Inventors: Kazuto Okamura, Chiba (JP); Kazutoshi Taguchi, Chiba (JP); Kazunori Ohmizo, Chiba (JP); Makoto Shimose, Chiba (JP); Katsuya Sakayori, Tokyo (JP); Terutoshi Momose, Tokyo (JP); Tomoko Togashi, Tokyo (JP); Michiaki Uchiyama, Tokyo (JP); Shigeki Kawano, Tokyo (JP)

Correspondence Address: RADER FISHMAN & GRAUER PLLC, LION BUILDING, 1233 20TH STREET N.W., SUITE 501, WASHINGTON, DC, 20036, US

(21) Appl. No.: 10/075,306

(22) Filed: Feb. 15, 2002

(30) Foreign Application Priority Data
Feb. 16, 2001 (JP) 40829/2001

(51) Int. Cl. H01L 21/461

(52) U.S. Cl. 438/689

(57) ABSTRACT

This invention relates to an HDD suspension and a process for its manufacture with high productivity and reliability. The HDD suspension of this invention is manufactured from a laminate composed of a stainless steel substrate, an insulating resin layer and a metal foil by wet etching the laminate by the use of a basic fluid. The insulating layer of the laminate is composed of plural layers of polyimide, every constituent layer exhibits a mean etching rate of 0.5 μm/min or more by a 50 wt % aqueous solution of KOH at 80° C., the layers in contact with the stainless steel substrate and the metal foil are those of polyimide (B) exhibiting a glass transition temperature of 300° C. or less and the adhesive strength between the layer of polyimide (B) and either the stainless steel substrate or the metal foil is 0.5 kN/m or more.

### TECHNICAL FIELD

This invention relates to an HDD suspension to be manufactured by the use of a laminate comprising a layer of insulating resin on a stainless steel substrate and to a process for manufacturing said HDD suspension.

### BACKGROUND ART

There has arisen a need for increased capacity and information transmission speed of HDD to be incorporated in computers at the present time. As for a suspension or a part which supports the head for reading magnetic recording used in HDD, structural switch-over is taking place from the conventional type of connecting gold-wire signal lines to the so-called wireless suspension in which signal lines of copper wires are formed directly on a stainless steel spring to cope with a trend for higher density.

As for the manufacture of a wireless suspension such as this, a process disclosed in JP96-45213A proposes to form a patterned insulating layer on a layer of resilient metal such as stainless steel by the use of photosensitive polyimide and then form a signal line on the insulating layer by the semiadditive process. In case a wireless suspension is manufactured by the aforementioned process, however, a conductor needs to be formed after the processing of polyimide and this tends to impose restrictions on designing of suspensions; for example, this presents difficulties in forming a part, the so-called flying lead, in which the conductor alone exists unsupported by other structural materials to connect the signal line with the magnetic head or other parts of circuitry.

To solve the aforementioned problems, Japanese patent publication JP9-293222A proposes a process for manufacturing a suspension for the magnetic head which comprises utilizing a laminate having a structure of resilient metal layer (such as stainless steel)/insulating layer/conductive layer, forming specified patterns on the layer of resilient metal and the conductive layer and removing the insulating layer by plasma etching. A process such as this has advantages in that the flying lead is easy to form and a suspension can be designed relatively free of restrictions. However, the dry etching process represented by the aforementioned plasma etching is a batch-type operation, frequently a vacuum process as well, and suffers from extremely poor productivity and extremely high equipment cost. Nevertheless, plasma etching has been used widely for the reason that any other process cannot perform patterning of polyimide when the existing laminates are used.

Wet etching of polyimide-based materials has been investigated as a substitute for dry ethcing and there has been a demand for materials suitable for wet etching. Regarding polyimides as constituent of polyimide-metal laminates useful for the manufacture of HDD suspensions, WO98/8216 (U.S. Pat. No. 6,203,918) discloses polyimdes which are relatively easy to etch by an organic alkali such as hydrazine but none which can be etched at a sufficient rate by an aqueous alkali solution of low toxicity. Materials exhibiting high etching rate in wet etching by an aqueous alkali solution are exemplified by commercially available polyimide films such as Kapton of DuPont and Apical of Kaneka Corporation; however, as these polyimide films show high glass transition temperature (hereinafter referred to as Tg) and do not by themselves show sufficient adhesiveness to metals, they encounter a problem that they are not applicable as they are to HDD suspensions requiring conductive circuits.

A process has been proposed to form a layer of metal such as copper on the aforementioned polyimide films by sputtering or plating, but the resulting material does not show sufficient adhesive strength between the metal and the polyimide film and poor dimensional stability. Moreover, it is substantially impossible to form a layer of stainless steel required for an HDD suspension by the process in question. Under the circumstances, there has been a strong demand for laminates useful for the manufacture of HDD suspensions such as the ones comprising an insulating resin layer which can be processed by wet etching by the use of an aqueous alkali solution and shows good adhesion to metal and for HDD suspensions to be manufactured by the use of said laminates.

### DISCLOSURE OF THE INVENTION

An object of this invention is to provide an HDD suspension to be manufactured from a laminate which maintains such characteristics as heat resistance and dimensional stability in heat treatment hitherto required for polyimide-based laminates, exhibits good adhesion between the metal foil and the insulating resin layer and comprises polyimide processable by wet etching by an aqueous alkali solution as the resin in the insulating layer. Another object of this invention is to provide a process for wet-etching said insulating resin layer in the aforementioned laminate by an aqueous alkali solution and to provide a process for manufacturing an HDD suspension.

This invention relates to an HDD suspension to be obtained by processing a laminate showing the following characteristics: the laminate comprises successive layers of a stainless steel substrate, an insulating resin and a metal foil, the insulating resin layer is composed of plural layers of polyimides, each constituent layer is etched at an average rate of 0.5 μm/min or more by a 50 wt % aqueous solution of potassium hydroxide at 80° C., the constituent polyimide layer in contact with the stainless steel substrate or the metal foil is polyimide (B) with a glass transition temperature of 300° C. or less, and the adhesive strength between polyimide (B) and either the stainless steel substrate or the metal foil is 0.5 kN/m or more.

Furthermore, this invention relates to a process for manufacturing an HDD suspension from the aforementioned laminate which comprises patterning the insulating resin layer by wet etching.

This invention will be described in detail below.

The laminate to be used for the manufacture of an HDD suspension of this invention is made by building up an insulating polyimide resin layer and a metal foil successively on a stainless steel substrate. Each constituent layer of the laminate may contain two or more layers, but preferably one layer.

The aforementioned stainless steel substrate is not restricted in any way as long as it is stainless steel. However, from the viewpoint of resilience and dimensional stability required for suspensions, it is preferably SUS304, more preferably SUS304 after tension-anneal treatment at 300° C. or more. The thickness of the substrate is preferably in the range of 10-70 μm, more preferably 15-30 μm.

The aforementioned metal foil is preferably a foil of copper or its alloy with a thickness of 3-20 μm. The foil of a copper alloy refers to a foil made of an alloy of copper and other element such as nickel, silicon, zinc and beryllium with the copper content amounting to 80% or more.

It is allowable to apply chemical or mechanical surface treatment to the stainless steel substrate and the metal foil for improving the adhesive strength.

The aforementioned insulating resin layer is composed of plural layers of polyimides and the polyimide in at least the layer existing in contact with the stainless steel substrate or the metal foil is polyimide (B) with a Tg of 300° C. or less. It is necessary for the glass transition temperature (Tg) to be 300° C. or less, preferably 200-250° C. Too high Tg deteriorates the adhesiveness and decreases the etching rate while too low Tg deteriorates the heat resistance.

The insulating resin layer is preferably constructed of a layer of polyimide (B) and a layer of low-thermal-expansion polyimide (A) with a coefficient of thermal expansion (hereinafter referred to as CTE) of 30×10⁻⁶/° C. or less. The CTE of the layer of polyimide (A) is necessarily 30×10⁻⁶/° C. or less, preferably 10×10⁻⁶·25×10⁻⁶/° C. Too high CTE makes it difficult to secure the planarity of an HDD suspension (including HDD suspension blank) after processing.

It is conceivable that the polyimide resin layer may satisfy the requirements for both polyimide (A) and polyimide (B). In such a case, the polyimide resin layer in contact with the stainless steel substrate or the metal foil is regarded as polyimide (B) and the intermediate polyimide layer as polyimide (A).

In case the insulating resin layer structurally contains a layer of polyimide (A), an example of a preferred structure is a three-layer structure of polyimide (B)/polyimide (A)/polyimide (B). What counts here is that the polyimide layer in contact with the stainless steel substrate and the metal foil is polyimide (B) and it is allowable for one or two layers or more of polyimide (A) or polyimide (B) or, if necessary, a layer of other resin (C) to exist in between. In case a layer of other resin (C) is allowed to exist, such other resin is advantageously polyimide from the viewpoint of etching characteristics and heat resistance.

The thickness of the layer of polyimide (B) existing in contact with the stainless steel substrate or the metal foil is preferably in the range of 0.5-7 μm, more preferably 0.5-5 μm. Any thickness in excess of this range is disadvantageous from the viewpoint of maintaining low-thermal-expansion property of the whole laminate and the planarity becomes difficult to maintain.

In case the insulating resin layer contains at least one layer of low-thermal-expansion polyimide (A), the thickness of the layer in question is preferably 3-75 μm, more preferably 5-50 μm. If the thickness exceeds this range, the drying efficiency falls when a solution of the polyimide is applied as coating and dried. However, when a film of polyimide (A) is prepared in advance and used to make a laminate by hot pressing, the aforementioned thickness range does not need to be observed rigidly. The total thickness of polyimide layers constituting the insulating resin layer is preferably 4-60 μm, more preferably 4-30 μm. Any thickness exceeding this range may develop the possibility of adversely affecting the resilience characteristics of a suspension and lowering the patterning accuracy in etching of polyimide while any thickness below this range may lower the insulation reliability of the polyimide insulating layer.

In case a layer of polyimide (A) is present, the thickness ratio of polyimide (B) to polyimide (A) in the insulating resin layer or the ratio (B)/(A) is suitably 0.05-1, preferably 0.1-0.5. When this ratio becomes too large, the CTE of the total insulating resin layer becomes large and the dimensional accuracy becomes lower or the planarity deteriorates during etching of the stainless steel substrate, the metal foil or the polyimide insulating layer.

The adhesive strength between the polyimide layer and the metal foil or that between the polyimide layer and the stainless steel substrate in the laminate needs to be 0.5 kN/m or more, preferably in the range of 1.0-5.0 kN/m. The adhesive strength here refers to the 180°peel strength at normal temperature (25° C.). If the adhesive strength is short of 0.5 kN/m, the metal foil may come off in later steps. This adhesive strength primarily depends on polyimide (B), although it may also be affected by the surface condition of the metal foil and the stainless steel substrate and polyimide (B) is properly selected for adequate strength.

The insulating resin layer constituting the laminate is composed of plural layers of polyimides and each of these layers needs to exhibit an average etching rate of 0.5 μm/min or more by a 50 wt % aqueous KOH solution at 80° C. In case the etching rate is short of 0.5 μm/min, there arise such problems as inability to obtain good etching shape, insufficient resistance of the resist to a polyimide etchant such as an aqueous alkali solution and reduction in production efficiency. In case a layer of polyimide (A) is used, its etching rate is 0.5 μm or more, preferably 2.01 μm or more, more preferably 4.0 μm or more. On the other hand, the etching rate of a layer of polyimide (B) is 0.5 μm or more, preferably 1.0 μm or more. The higher the etching rate, the better the etching shape becomes. In order to obtain a good etching shape, it is desirable to change the ratio of the etching rate of each layer a little and it is advantageous to set the ratio of the etching rate of polyimide (A) to that of polyimide (B) or the ratio (A)/(B) at 1.05-20, preferably 2-10.

The methods for determining the etching rate, Tg, adhesive strength and CTE in this invention are described in detail later in the examples.

Polyimides present in layers in the insulating resin layer are either synthesized in a known manner or obtained as commercially available polyimide films. Polyimides satisfying the properties required for this invention are preferably those which are obtained by the reaction of a diamine with a tetracarboxylic acid dianhydride. The tetracarboxylic acid dianhydrides here include tetracarboxylic acids, their acid chlorides and those compounds which react with diamines to form polyimides. Of the compounds mentioned, a tetracarboxylic acid dianhydride is preferable for ease of synthesizing polyamic acids. Polyimides mean polymers containing the imide group in their structure such as polyimides, polyamideimides, polyetherimides, polysiloxaneimides and polybenzimidazoleimides.

Diamines or tetracarboxylic acid dianhydrides useful for the preparation of polyimide (B) are those diamines or tetracarboxylic acid dianhydrides which are known to give polyimides of relatively high adhesive strength or a mixture of diamines or tetracarboxylic acid dianhydrides containing said diamines or tetracarboxylic acid dianhydrides as principal components.

A preferred tetracarboxylic acid dianhydride is one kind or two kinds or more of tetracarboxylic acid dianhydrides selected from pyromellitic dianhydride (PMDA), 3,4,3′,4′-benzophenonetetracarboxylic acid dianhydride (3,4,3′,4′-BTDA), 3,4,3′,4′-diphenylsulfonetetracarboxylic acid dianhydride (3,4,3′,4′-DSDA) and a tetracarboxylic acid dianhydride of the trimellitic anhydride ester type (TMDA) represented by the following general formula (1) or a mixture of tetracarboxylic acid dianhydrides containing 50 mol % or more, preferably 70 mol % or more, more preferably 80 mol % or more, of the aforementioned tetracarboxylic acid dianhydrides.

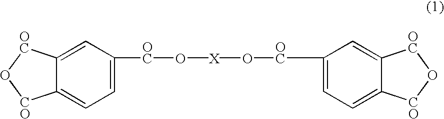

The group X in formula (1) designates a linear or branched divalent aliphatic hydrocarbon group with 2-30 carbon atoms and X may contain a substituent such as a halogen and an aryl group in the main chain or side chain. The Tg tends to drop as the number of carbon atoms in X increases and a compound of formula (1) containing a large number of carbon atoms may be used effectively together with pyromellitic dianhydride which has a property of raising the Tg. However, a too large number of carbon atoms in X deteriorates the heat resistance. Therefore, X preferably contains 2-20 carbon atoms and, more preferably, X is an alkylene group (including alkylidene group) containing 2-10 carbon atoms.

The aforementioned 3,4,3′,4′-BTDA, 3,4,3′,4′-DSDA and TMDA may be used singly, but they provide good etching quality when used together with PMDA. As PMDA tends to raise the Tg of polyimide when used in a large amount, however, it is preferably used in an amount accounting for 80 mol % or less, preferably 30-60 mol %, of the total tetracarboxylic acid dianhydrides. In such a case, the amount used of 3,4,3′,4′-BTDA, 3,4,3′,4′-DSDA and TMDA as tetracarboxylic acid dianhydride is 20 mol % or more, advantageously 40-70 mol %, of the total tetracarboxylic acid dianhydrides.

It is allowable to use other tetracarboxylic acid dianhydrides in addition to the aforementioned and such other tetracarboxylic acid dianhydrides include 3,3′,4,4′-biphenyltetracarboxylic acid dianhydride and 4,4′-oxydiphthalic acid dianhydride. Since the use of these tetracarboxylic acid dianhydride in large amounts markedly deteriorate the wet etching quality of the product polyimide by an aqueous alkali solution, a preferable amount of these acid dianhydrides, if used, is 30 mol % or less, preferably 10 mol % or less, of the total tetracarboxylic acid dianhydrides.

A preferred diamine is one kind or two kinds or more of diamines selected from 1,3-bis(3-aminophenoxy)benzene (1,3-BAPB), 3,4′-diaminodiphenyl ether (3,4′-DADE), a diamine (DA-2) represented by the following general formula (2) and a diamine (DA-3) represented by the following general formula (3) or a mixture of diamines containing 50 mol % or more, preferably 70 mol % or more, of the aforementioned diamines.

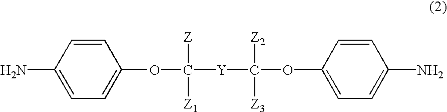

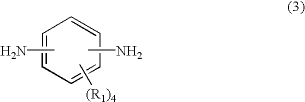

The groups Z, Z₁, Z₂ and Z₃ in the aforementioned general formula (2) designate hydrogen or an alkyl group with 1-3 carbon atoms, preferably hydrogen or methyl, and Y designates a linear or branched divalent aliphatic hydrocarbon group containing 1-5 carbon atoms with or without a substituent, preferably methylene or ethylene. The group R₁ in the aforementioned general formula (3) designates hydrogen, an alkyl group with 1-10 carbon atoms, an alkoxy group with 1-10 carbon atoms and a halogen, preferably hydrogen or methyl.

In case DA-3 represented by the aforementioned formula (3) is chosen as a diamine, the Tg of the product polyimide becomes higher as the amount used of the diamine in question increases and, as a result, hot pressing of the polyimide to the stainless steel substrate or the metal foil becomes difficult to perform and the adhesive strength tends to become weaker. Therefore, the amount used of the diamine in question is desirably 80 mol % or less, preferably 60 mol % or less, of the total diamines. The simultaneous use of DA-3 and PMDA raises the Tg still further and it is advisable to use not too much of both.

It is possible to use other diamines besides the aforementioned; for example, 4,4′-diamino-2,2′-dimethylbiphenyl, 4,4′-DADE, 2,2′-bis[4-(4-aminophenoxy)phenyl]propane (BAPP), 4,4′-bis(3-aminophenoxy)biphenyl, 4,4′-diaminodiphenylpropane, 3,3′-diaminobenzophenone and 4,4′-diaminodiphenyl sulfide. It is advisable to limit the use of these diamines to 50 mol % or less, preferably 10 mol % or less.

It is desirable for the insulating resin layer to contain a layer other than the aforementioned layer of polyimide (B) and there is one restriction imposed on the polyimide layer in question, that is, the etching rate by a 50% aqueous KOH solution at 80° C. is 0.511 m or more. Preferably, a layer of low-thermal-expansion polyimide (A) with a coefficient of linear expansion of 30×10⁻⁶/° C. is used as such other layer. This low-thermal-expansion polyimide may be prepared from a suitable combination of diamines and tetracarboxylic acid compounds known in a large number of literatures and patents or a commercially available polyimide film may used as such.

The CTE is determined by heating the resin film to 250° C. and cooling it at a rate of 5° C./min and measuring the mean CTE in the temperature range from 240° C. to 100° C. Concretely, the specimen after completion of the imidation is heated in a thermomechanical analyzer (a product of Seiko Instruments Co., Ltd.) to 250° C., maintained at this temperature for 10 minutes and cooled at a rate of 5° C./min and the mean coefficient of thermal expansion in the range from 240° C. to 100° C. is determined.

There is no restriction on the tetracarboxylic acid dianhydride for use in the synthesis of polyimide (A) and PMDA is preferred. The use of PMDA in an amount corresponding to 60 mol % or more, preferably 80 mol % or more, of the total tetracarboxylic acid dianhydrides helps the product polyimide to manifest effectively the properties of adequate etching by an aqueous alkali solution and of low thermal expansion.

Other tetracarboxylic acid dianhydrides include 3,4,3′,4′-BTDA, 3,4,3′,4′-DSDA, 3,3′,4,4′-biphenyltetracarboxylic acid dianhydride and 4,4′-oxydiphthalic acid dianhydride. 3,3′,4,4′-Biphenyltetracarboxylic acid dianhydride and 4,4′-oxydiphthalic acid dianhydride give polyimide which effectively provides low moisture absoprtion but suffers marked loss in etching quality by an aqueous alkali solution and they must be used in an amount corresponding to 40 mol % or less, advantageously 5-20 mol %, of the total tetracarboxylic acid dianhydrides. Moreover, the use of 3,4,3′,4′-BTDA and 3,4,3′,4′-DSDA is preferably limited to 50 mol % or less, advantageously 5-30 mol %, of the total tetracarboxylic acid dianhydrides from the viewpoint of obtaining low thermal expansion.

Preferable examples of diamines useful for the synthesis of low-thermal-expansion polyimides are para-phenylenediamine (DAP), meta-phenylenediamine, 2,4-diaminotoluene, 1,3-BAPB, 3,4′-DADE and 4,4′-diamino-2′-methoxybenzanilide (DAMBA) and DAP and DAMBA give polyimides which are particularly effective for manifesting the property of low thermal expansion. Diamines such as 4,4′-diamino-2,2′-dimethylbiphenyl and 4,4′-DADE are also effective as they give polyimides which manifest the property of low thermal expansion without significant loss of etching quality and, moreover, these diamines are expected to be effective for providing low moisture absorption. In addition, diamines such as BAPP, 4,4′-bis(3-aminophenoxy)biphenyl, 4,4′-diaminodiphenylpropane, 3,3′-diaminobenzophenone and 4,4′-diaminodiphenyl sulfide may be used in combination with the aforementioned diamines; however, these diamines, particularly BAPP or 4,4′-bis(3-aminophenoxy)biphenyl, when added even in a small amount, markedly deteriorates the etching quality of the product polyimide and the addition of these diamines is restricted.

Polyimides to be used in constituent layers of the insulating resin layer in this invention can be prepared by a known method. For example, a tetracarboxylic acid and a diamine in roughly equimolar amounts are allowed to react in a solvent at 0-200° C., preferably at 0-100° C., to give a polyimide precursor and the precursor is imidized to polyimide.

Solvents useful for this reaction include N-methylpyrrolidone, methylformamide, dimethylacetamide (DMAc), dimethyl sulfoxide, dimethyl sulfate, sulfolane, butryolactone, cresol, phenol, halogenated phenol, cyclohexane, dioxane, tetrahydrofuran, diglyme and triglyme.

In order to reduce warpage which occurs when either of the stainless steel substrate or the metal foil of the laminate of this invention is removed by etching, the difference in thermal expansion between the metal foil and the insulating resin layer should desirably be small; concretely, the coefficient of thermal expansion of the whole insulating resin layer is desirably 30×10⁻⁶/° C. or less. Moreover, in order to prevent occurrence of undulation and warpage during processing of the laminate into an HDD suspension or after shaping by etching in the intermediate step, an effective and desirable means is to reduce the curl of the insulating resin layer itself to a radius of curvature of 5 mm or more. A simple and effective method for the reduction of the curl of the insulating resin layer is to control the thickness of the layer of polyimide (B) existing in contact with the stainless steel substrate and the metal foil.

Although a known method is applicable to the manufacture of the aforementioned laminate, the following method is preferred: a solution of polyimide or its precursor suitable for the formation of a layer of polyimide (B) is applied to the stainless steel substrate and dried, then solutions of polyimides for the formation of one or more additional layers are successively applied and dried, finally a solution of polyimide for the formation of a layer of polyimide (B) is applied and dried, and the assembly is heated at 200° C. or more and hot-pressed to the metal foil. Preferably, one or more additional layers of polyimides are successively formed layers of low-CTE resin (A) and Low-Tg resin (B).

In the aforementioned steps for drying and curing, rapid heating at high temperature forms a skin on the surface of the resin while hindering smooth evaporation of the solvent or causing foaming and the heat treatment should be performed by gradually raising the temperature.

Hot pressing thereafter can be performed in the usual manner by the use of an ordinary hydropress, a vacuum-type hydropress, an autoclaving vacuum press and a continuous thermal laminator. Of these methods, a vacuum hydropress is preferred as it provides sufficient pressure for pressing, readily removes residual volatile matters and prevents the oxidation of the metal foil. The temperature during hot pressing is not restricted in any specific way, but it is desirably equal to or higher than the Tg of the polyimide in use, preferably higher than the Tg by 5-150° C. The pressure during hot pressing varies with the kind of press in use and it is adequately 1-50 MPa. In case a hydropress is used for hot pressing, a plural number of laminates can be prepared in one operation by having a sheet of stainless steel substrate which is laminated on one side to layers of polyimide and a sheet of metal foil ready, placing one sheet upon another several times and laminating the whole assembly under heat and pressure by a hot press.

In case a polyimide film is used as one of the polyimide layers in the insulating resin layer, a solution of polyimide or its precursor for the formation of polyimide (B) is applied to both sides of the polyimide film, dried, and heated at 200° C. or more, the resulting insulating resin film is put between the stainless steel substrate and the metal foil and hot-pressed. Another procedure is to apply a solution of resin for the formation of polyimide (B) to the stainless steel substrate and the metal foil, dry and heat at 200° C. or more to form a layer of polyimide on the stainless steel substrate and the metal foil in advance and press these polyimide layers and a film of polyimide (A) together under heat. Preferable layered structures are the following wherein S stands for the stainless steel substrate, M for the metal foil, (A) for the layer of polyimide (A) and (B) for the layer of polyimide (B): (1) S/(B)/(A)/(B)/M; (2) S/(B)/(A)/(B)/(B)/(A)/(B)/M; (3) S/(B)/(A)/(A)/(B)/M.

An HDD suspension of this invention is manufactured starting with the laminate prepared in this manner. The suspension as used in this invention means a resilient part on which the head for reading information form a variety of recording media such as hard disks is mounted. The head does not need to be mounted or it may be partly integrated with parts for other purposes. Moreover, it includes other parts such as HDD suspension flexures for use in HDD suspensions in combination with other parts such as mounts and load beams.

### BRIEF DESCRIPTION OF THE DRAWINGS

FIG. 1 is a process diagram illustrating the manufacture of an HDD suspension by the use of a laminate.

FIG. 2 is a scanning electron micrograph of the cross section of the insulating layer in an example.

FIG. 3 is a scanning electron micrograph of the cross section of the insulating layer in a comparative example.

### PREFERRED EMBODIMENTS OF THE INVENTION

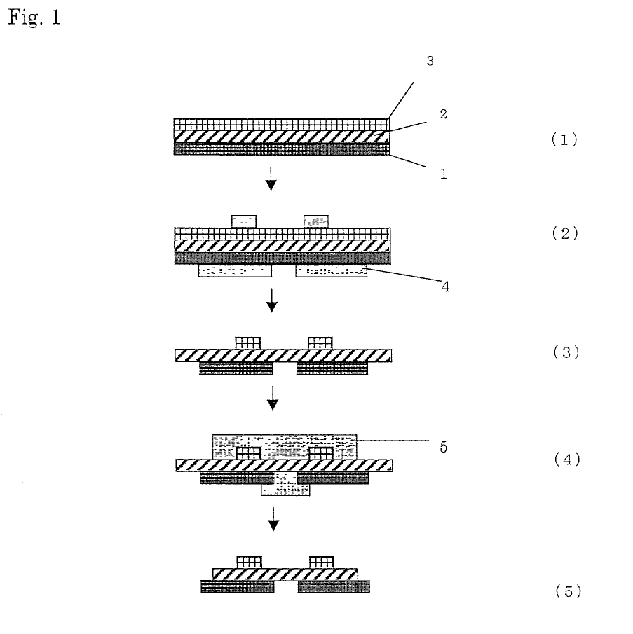

The process for manufacturing an HDD suspension of this invention will be described below with reference to the process diagram in FIG. 1, but it is not limited thereto. FIG. 1 (1) shows the cross section of a laminate which is constructed of a stainless steel substrate 1, an insulating resin layer 2 and a metal foil 3. FIG. 1 (2) illustrates an assembly formed by laminating a photosensitive acrylic dry film resist 4 to the surfaces of both the stainless steel substrate 1 and the metal foil 3. The resist is exposed through a specified photomask pattern and developed to form a resist pattern. Dry film resists have a merit of being readily available in a specified film thickness. There is no specific restriction on dry film resists in use and an alkali development type or a lactic acid development type may be used. Depending upon the wanted pattern, a dry film resist can be selected in consideration of the kind of developer to be used and the properties of negative or positive resists.

Liquid resists may be used in place of dry film resists here. Examples are acrylic resists, novolak resists and casein resists, though there is no specific restriction on them.

The stainless steel substrate and the metal foil of the laminate on which a resist pattern has been formed are submitted to wet etching by an etchant. The etchant to be used here is usually ferric chloride or cupric chloride, but any substance capable of dissolving the target metal may be used without restriction. In this case, the metallic layers may be wet-etched, one side at a time, by the one-sided wrapping process.

FIG. 1 (3) illustrates a three-layer laminate composed of the insulating polyimide layer in the middle and the patterned metallic layers on both sides formed by patterning the metallic layers followed by stripping the resist patterns by a stripping solution such as NaOH.

The next step is to process the insulating layer having the patterned metallic layers on both sides by wet etching. Wet etching here means etching of the insulating layer by a suitably selected etchant. From the viewpoint of operability, a preferred procedure is to perform patterning by the use of a photoresist, but another acceptable procedure is to etch polyimide by the use of the metallic layer in place of a resist pattern and then pattern the metallic layer to a desired shape.

Concretely, a resist for processing the insulating layer is formed in the region where the insulating layer is to be left on the upper and lower sides of the insulating layer on which wiring is formed by processing the patterned metallic layers.

In the course of this operation, the resist pattern for processing the insulating layer is formed so that it overlaps the metallic layer usually patterned on the insulating layer. If the resist pattern for processing the insulating layer is formed only in the region where the insulating layer is to be left without overlapping, the etchant used for etching polyimide acts on the resist pattern to form a gap between said pattern and the metallic layer and this allows the etchant to force its way through the gap with the possibility of etching the part which is to be left originally as the insulating layer.

FIG. 1 (4) illustrates this state of affairs and the resist pattern for processing the insulating layer 5 is formed in such a way as to overlap the patterned stainless steel substrate 1 and metal foil 3 on the insulating layer 2.

In order to form a resist pattern for processing the insulating layer, a resist for this purpose is formed on both sides of the insulating layer by dip coating, roll coating, die coating or lamination. The resist is then exposed and developed in accordance with the specified photomask pattern. A dry film resist for this use is not restricted in any specific way and an alkali or lactic acid development type may be used. Depending upon the wanted pattern, suitable selection may be made in consideration of the developer, the properties of negative or positive type and resistance to etchants. The resist for processing the insulating layer may be formed by printing without resort to exposure and development.

What follows next is the etching of the insulating layer and an alkali-amine etchant such as disclosed in JP10-97081A is used suitably, though not limited thereto. Concretely, an aqueous alkaline solution is desirable and a basic fluid with a pH of preferably 9 or more, more preferably 11 or more, is used. The basic fluid may be an organic or inorganic alkali or a mixture of the two.

As for the etching conditions, the temperature causes no problem if it is in the range where the etchant remains liquid and, in consideration of the fact that a large number of etchants occur as aqueous solutions and of the operability, etching is performed preferably in the range of 20-100° C., more preferably 30-95° C. If the temperature is below 20° C., the dissolved components tend to precipitate and, moreover, the etching rate of the polyimide resin layer falls markedly to reduce the productivity and, at the same time, to develop the possibility of damaging the shape of the polyimide pattern to be obtained. On the other hand, above 100° C., the components of the etchant evaporate vigorously causing a large change in concentration during the operation and it is not possible to obtain a stable etching shape. In case the etchant is a mixture with an extremely low or high boiling point, it is desirable to set the treating temperature at a corresponding level. When the temperature distribution inside the etchant is wide, the patterning accuracy of the etched polyimide resin layer tends to scatter and it is desirable to keep the etchant at as uniform a temperature as possible.

The polyimide resin layer can be etched by simply immersing the resin in an etchant in accordance with a procedure such as dipping, spraying and submerged spraying, although the procedure is not limited to any specified one. The time for etching the polyimide resin layer is set according to the etching rate and the thickness of the resin layer and the kind and temperature of the etchant used and, although the etching time is not restricted specifically, it is preferably 2-1,800 seconds, more preferably 5-900 seconds. If the etching time is shorter than 2 seconds, there is the possibility of the patterning accuracy of polyimide scattering widely after etching. On the other hand, if the etching time is longer than 1,800 seconds, there is the possibility that a good etching shape of polyimide may not be obtained as the productivity drops and at the same time some of the resists in use may break or come away.

The laminate in which the stainless steel substrate and the metal foil have been patterned may be etched on one side at a time while masking substantially the whole surface of the other side or etched on both sides simultaneously depending upon the demanded etching shape and productivity.

The next step is stripping of the resist pattern for processing the insulating layer used as a masking material of wet etching and this completes the processing of the insulating material. In case the resist is alkali-strippable, stripping is generally performed by an aqueous alkali solution. However, when the insulating polyimide layer exhibits poor resistance to alkali, an organic alkaline substance such as ethanolamine may be used.

FIG. 1 (5) illustrates an HDD wireless suspension formed by the aforementioned method. The surface of the metal foil which serves as wiring may be plated with gold. The bath for gold plating is not restricted and it may be cyanide or acid. A pretreatment such as degreasing, neutralization and prevention of substitution may be performed. In degreasing, it does not matter whether the degreasing agent in use is an alkali or an acid as long as it is effective for cleaning the surface of the metal.

The plating with gold is a surface treatment primarily aimed at providing electrical contact between the magnetic head slider and the suspension and that between the suspension and the control side; therefore, besides plating with gold, plating with nickel/gold also accomplishes the purpose satisfactorily and occasionally solder plating or printing is substituted for the gold plating. In ase nickel is used for plating, the bath may be chosen from bright, mat and semi-bright. In FIG. 1 (5) which shows a gold-plated HDD suspension, the layer of plated gold is too thin to show clearly in the figure.

### EXAMPLES

This invention will be described concretely with reference to the accompanying examples. The properties in the examples are evaluated as follows.

Measurement of Glass Transition Temperature (Tg)

With the aid of a viscoelastic analyzer (RSA [symbol] available from Rheometric Science EF Co., Ltd.), a 10 mm-wide test specimen is heated from room temperature to 400° C. at a rate of 10° C./min while receiving vibration of 1 Hz and the glass transition temperature is obtained from the maximum loss tangent (tan δ).

Measurement of Coefficient of Thermal Expansion (CTE)

With the aid of a thermomechanical analyzer (available from Seiko Instruments Co., Ltd.), a test specimen is heated to 250° C., kept at this temperature for 10 minutes and cooled at a rate of 5° C./min and the coefficient of thermal expansion is obtained by calculating the mean between 240° C. and 100° C.

Measurement of Etching Rate

A layer of polyimide is formed on a stainless steel foil, the thickness of the polyimide layer is determined, the polyimide layer is then immersed together with the stainless steel foil in a 50% aqeuous solution of KOH at 80° C., the time for complete disappearance of the polyimide is measured and the value obtained by dividing the initial thickness by the time required for etching is taken as etching rate. Where the polyimide specimen takes a long time to etch, the value obtained by dividing a loss in thickness by the time required for causing the loss is taken as etching rate.

Measurement of Adhesive Strength

A specimen for measuring the adhesive strength between a metal foil and polyimide is prepared by forming a layer of polyimide on a stainless steel foil, laminating a copper foil to the polyimide layer by hot pressing and punching the resulting laminate into a piece, 10 mm×160 mm, by a punching press. The stainless steel side and the copper foil side of the specimen are respectively pasted to a fixed plate and the 180 peel strength of each metal foil is determined with the aid of a tensile tester (Strograph-M1, available from Toyo Seiki Co., Ltd.).

Synthetic examples of polyimide precursor solutions are described below. Synthetic Example 1 relates to a polyimide precursor solution use for a layer of low-CTE polyimide (A) and Synthetic Examples 2-6 relate to polyimide precursor solutions use for layers of low-Tg polyimide (B).

The following symbols are used in the examples.

DAMBA: 4,4′-diamino-2′-methoxybenzanilide

4,4′-DADE: 4,4′-diaminodiphenyl ether

3,4′-DADE: 3,4′-diaminodiphenyl ether

1,3-BAPB: 1,3-bis(3-aminophenoxy)benzene

DAP: p-phenylenediamine

BADP: 1,3-bis(4-aminophenoxy)-2,2′-dimethylpropane

BAPP: 2,2′-bis[4 (4-aminophenoxy)phenyl]propane

3,4,3′,4′-DSDA: 3,4,3′,4′-dphenylsulfonetetracarboxylic acid dianhydride

3,4, 3′,4′-BTDA: 3,4,3′,4′-benzophenonetetracarboxylic acid dianhydride

PMDA: pyromellitic dianhydride

### Synthetic Example 1

A solution of diamines was prepared by dissolving 20.5 g of DAMBA and 10.6 g of 4,4′-DADE in 340 g of solvent DMAc with stirring in a 500-ml separable flask. The solution was cooled in an ice bath and 28.8 g of PMDA was added to the cold solution in a current of nitrogen. The solution was allowed to return to room temperature and was allowed to undergo polymerization with stirring for 3 hours to give a viscous solution or polyimide precursor solution A.

A stainless steel foil (SUS304, tension-annealed, available from Nippon Steel Corporation) was coated with polyimide precursor solution A by an applicator to an after-cure thickness of 15 μm, dried at 110° C. for 5 minutes and heated stepwise at 130° C., 160° C., 200° C., 250° C., 300° C. and 360° C. for 3 minutes at each temperature level to form a polyimide layer on the stainless steel foil. The polyimide layer was tested for etching rate by immersing it together with the stainless steel foil in a 50% aqueous solution of KOH at 80° C. and the etching was found to have proceeded at a rate of 13.71 μm/min. Separately, a polyimide layer was formed on the stainless steel foil, the foil was etched off by an aqueous solution of ferric chloride and the remaining polyimide film was measured for CTE which was 17.7×10⁻⁶/° C.

### Synthetic Example 2

A solution was prepared by dissolving 22.1 g of BADP and 6.6 g of 3,4-DADE in 340 g of DMAc. To this solution were added 9.7 g of PMDA and 21.5 g of 3,4,3′,4′-BTDA in a current of nitrogen. Thereafter, the solution was allowed to undergo polymerization for 3 hours with stirring to give a viscous solution or polyimide precursor solution B.

A 15 μm-thick polymide layer was formed on the stainless steel foil using polyimide precursor solution B and evaluated as in Synthetic Example 1. The etching rate of the polyimide layer was 2.1 μm/min and the polyimide film obtained by etching off the stainless steel foil showed a Tg of 235° C. when evaluated by a viscoelastic analyzer.

### Synthetic Example 3

A solution was prepared by dissolving 22.6 g of 1,3-BAPB and 3.6 g of DAP in 340 g of DMAc. To this solution were added 9.7 g of PMDA and 24.1 g of 3,4,3′,4′-DSDA in a current of nitrogen. Thereafter, the solution was allowed to undergo polymerization for 3 hours with stirring to give a viscous solution or polyimide precursor solution C.

The polyimide layer obtained from polyimide precursor solution C showed an etching rate of 1.6 μm/min and a Tg of 216° C.

### Synthetic Example 4

A solution was prepared by dissolving 25.4 g of 3,4′-DADE in 340 g of DMAc. To this solution were added 14.0 g of PMDA and 20.6 g of 3,4,3′,4′-BTDA in a current of nitrogen. Thereafter, the solution was allowed to undergo polymerization for 3 hours with stirring to give a viscous solution or polyimide precursor solution D.

The polyimide layer obtained from polyimide precursor solution D showed an etching rate of 0.8 μm/min and a Tg of 286° C.

### Synthetic Example 5

A solution was prepared by dissolving 21.4 g of 1,3-BABP and 3.4 g of DAP in 340 g of DMAc. To this solution were added 9.2 g of PMDA and 26.0 g of ethylene glycol bis(trimellitate anhydride). Thereafter, the solution was allowed to undergo polymerization for 3 hours with stirring to give a viscous solution or polyimide precursor solution E.

The polyimide layer obtained from polyimide precursor solution E showed an etching rate of 1.2 μm/min and a Tg of 203° C.

### Synthetic Example 6

A solution was prepared by dissolving 35.5 g of BAPP in 340 g of DMAc. To this solution were added 7.6 g of PMDA and 16.9 g of 3,4,3′,4′-BTDA in a current of nitrogen. Thereafter, the solution was allowed to undergo polymerization for 3 hours with stirring to give a viscous solution or polyimide precursor solution F.

The polyimide layer obtained from polyimide precursor solution F showed an etching rate of 0.2 μm/min and a Tg of 280° C.

### Example 1

A stainless steel foil (SUS304, tension-annealed, 20 μm-thick, available from Nippon Steel Corporation) was coated with polyimide precursor solution B of Synthetic Example 2 by a bar coater to an after-cure thickness of 1 μm, dried at 110° C. for 3 minutes, coated further with polyimide precursor solution A of Synthetic Example 1 to an after-cure thickness of 14 μm, dried at 110° C. for 10 minutes, coated still further with polyimide precursor solution C of Synthetic Example 3 to an after-cure thickness of 1 μm, dried at 110° C. for 3 minutes, and then heated stepwise at 130° C., 160° C., 200° C., 250° C., 300° C. and 360° C. for 3 minutes at each temperature level to complete imidation and form a 16 μm-thick insulating layer consisting of three polyimide layers on the stainless steel foil. A copper alloy foil (C7025, 18 μm-thick, available from Olin Sommers Co., Ltd.) was placed on top of the polyimide layer with the roughened side of the alloy foil facing the polyimide layer and hot-pressed in a vacuum press at 15 MPa and 320° C. for 20 minutes to give a laminate having a structure of stainless steel foil/low-Tg resin layer/low-CTE resin layer/low-Tg resin layer/copper alloy foil.

The adhesive strength of the laminate was found to be 2.0 kN/m between stainless steel and polyimide and 2.4 kN/m between copper alloy and polyimide respectively and abnormalities such as blistering and stripping were not observed when the laminate was tested for heat resistance in an oven at 300° C. for 1 hour. The three-layer polyimide film obtained by etching off the stainless steel and copper alloy foils exhibited a CTE of 24.0×10^{-6/° C.}

A photosensitive acrylic dry film resist of alkali development type was laminated to both stainless steel and copper alloy foils of the laminate at 100° C. and, with the aid of an exposure equipment, exposed to the g line through a specified photomask pattern at a suitable integrated exposure, exposed further at a 1% integrated exposure of 150 mJ/cm² at 30° C. and developed by a 1% aqueous solution of Na₂CO₃ to form a specified resist pattern.

The stainless steel and copper alloy foils were simultaneously etched by an aqueous solution of FeCl₃ to form a specified shape from each foil and the resist was stripped by an aqueous solution of NaOH.

A dry film resist of alkali development type as a resist for processing the insulating layer was laminated at 100° C. to both sides of the laminate in which the stainless steel and copper alloy foils have been shaped in a specified way and, with the aid of an exposure equipment, the resist was exposed to the g line at a suitable integrated exposure and then spray-developed by a 1% aqueous solution of Na₂CO₃ to shape the resist for processing the insulating layer in a specified way.

The laminate on which the resist pattern for processing the insulating layer had been formed was immersed for 180 seconds in a polyimide etchant (TPE-3000, available from Toray Engineering Co., Ltd.) which had been stirred sufficiently to a uniform temperature of 80° C. to etch the polyimide insulating film to a specified shape. Thereafter, the resist pattern for processing the insulating layer was stripped by an aqueous solution of NaOH at 50° C. to give an etched part.

A layer of gold was formed on the copper alloy foil of the etched part in a cyanide gold-plating bath (available from Nippon Kohjundo Kagaku K.K.) by passing an electric current at a current density (Dk) of 0.4 A/dm² for approximately 4 minutes at 65° C. to give a flexure for an HDD wireless suspension.

The stainless steel substrate, the copper alloy layer and the polyimide insulating layer of the flexure thus obtained were etched in good condition and free from warpage and undulation which might cause problems in practice.

### Example 2

A laminate having a structure of stainless steel/polyimide insulating layer/copper alloy layer was prepared as in Example 1 while making the following changes in the procedure: polyimide precursor solution D was substituted for polyimide precursor solution B, polyimide precursor solution E was substituted for polyimide precursor solution C, the polyimide E layer was made 3 μm thick, the whole polyimide insulating layer was made 18 μm thick and the pressing temperature of the vacuum press was changed from 320° C. to 300° C. The adhesive strength of the laminate was 1.8 kN/m between stainless steel and polyimide and 1.6 kN/m between copper alloy and polyimide respectively and no abnormalities were observed in the test for heat resistance conducted at 300° C. The CTE of the whole polyimide insulating layer was 25.5×10⁻⁶/° C.

The etching of the polyimide in the laminate was then performed as in Example 1 except for performing the etching for 240 seconds to give a flexure of an HDD wireless suspension. The stainless steel substrate, the copper alloy layer and the polyimide insulating layer of the flexure were etched in good condition and free from warpage and undulation which might cause problems in practice.

### Comparative Example 1

A laminate having a structure of stainless steel/polyimide insulating layer/copper alloy layer was prepared as in Example 1 except for substituting polyimide precursor solution F for polyimide precursor solution C and changing the pressing temperature of the vacuum press from 320° C. to 340° C. The adhesive strength of the laminate was 1.9 kN/m between stainless steel and polyimide and 1.5 kN/m between copper alloy and polyimide respectively and no abnormalities were observed in the test for heat resistance conducted at 300° C. The CTE of the whole polyimide insulating layer was 24.3×10^{-6/° C.}

The etching of the polyimide in the laminate thus obtained was performed as in Example 1 except for setting the etching time at three levels of 180 seconds, 240 seconds and 600 seconds to give a flexure for an HDD wireless suspension. The stainless steel substrate and the copper alloy layer were etched in good condition and free from warpage and undulation which might cause problems in practice. However, because of the use of a polyimide layer showing a low etching rate of 0.2 μm/min or less by a 50% aqueous solution of KOH at 80° C. as a low-Tg resin layer on the copper alloy side, the polyimide layer in question was shaped like an overhang and was not fit for practical use.

### Comparative Example 2

The laminate obtained in Comparative Example 1 was processed as in Example 1 to give a flexure for an HDD wireless suspension while making the following changes; a dry film resist for plasma etching was used in place of the resist for processing the insulating layer of Example 1 and the polyimide insulating layer was dry-etched from the copper alloy side for a given period of time and then dry-etched from the stainless steel side for a given period of time in a plasma etching machine by the use of a mixture of halogen-containing gases at a plasma pressure of 25 Pa with application of high frequency.

The stainless steel substrate and the copper alloy layer of the flexure were etched in good shape. The etched shape of the polyimide insulating layer was good when compared with that in Comparative Example 1, but conspicuous unevenness was confirmed on the etched surface along the edge. Moreover, the temperature rose somewhat in the course of dry etching and gentle warpage was confirmed in the flexure for an HDD wireless suspension.

In order to explain the effect of this invention in detail, Example 1 (patterning of the polyimide insulating layer by wet etching) will be compared in detail with Comparative Example 2 (patterning of the polyimide insulating layer by plasma etching) below. In the following description, the flexure for an HDD wireless suspension obtained in Example 1 is referred to as sample A and that in Comparative Example 2 as sample B.

Evaluation of Shape

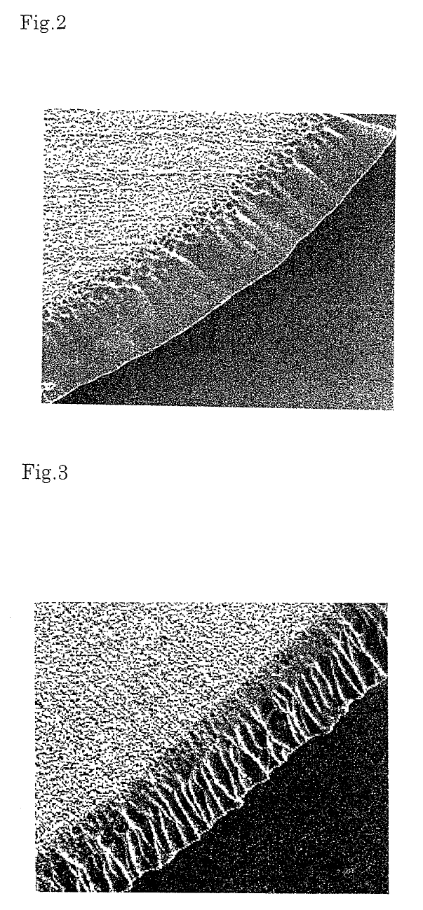

The scanning electron micrographs of the cross section of samples A and B are respectively shown in FIGS. 2 and 3. Sample A shown in FIG. 2 has an extremely smooth surface along the edge while sample B etched by plasma shown in FIG. 3 has an exceptionally uneven surface along the edge. The cross section of the wet-etched polyimide layer is generally much smoother than the plasma-etched polyimide layer, although it depends on the composition of the polyimide layer. For this reason, the wet-etched polyimide layer is well suited for use in suspensions for which minimal dust generation is demanded.

Evaluation of Dust Generation

Samples A and B which have been used for evaluation of pattern shape were immersed in filtered distilled water, irradiated with ultrasonic wave for 1 minute in an apparatus for ultrasonic wave irradiation and evaluated for generation of dust. The results are shown in Table 1. The evaluation was made with the aid of an apparatus for automatic measurement of fine particles in liquid available from HIAC/ROYCO Co., Ltd.

TABLE 1

| | |
|---|---|
| Particle diameter | No. of particles |

| (μm) | Sample A | Sample B |
|---|---|---|
| 1.0 | 402 | 736 |
| 2.0 | 245 | 407 |
| 3.0 | 104 | 171 |
| 5.0 | 57 | 84 |
| 10.0 | 24 | 33 |
| 15.0 | 8 | 14 |
| 25.0 | 2 | 4 |

Comparison of the aforementioned results indicates that sample A prepared by wet etching generates less dust. This is likely due to the cross-sectional shape formed by etching and wet etching helps to manufacture a suspension generating less dust than plasma etching.

This invention makes it possible to manufacture an HDD suspension from a laminate of high reliability which undergoes a minimal dimensional change, shows good resistance to heat and develops sufficient adhesive strength toward a metal foil. This manufacturing method is effective for improving productivity and lowering the cost. The polyimide insulating layer can be etched by an aqueous alkali solution and the manufactured suspension generates a reduced amount of dust and is highly reliable.

What is claimed is:

1. An HDD suspension to be obtained by processing a laminate which is constructed of an insulating resin layer and a metal foil successively formed on a stainless steel substrate and satisfies the following conditions; the insulating resin layer has plural layers of polyimides and every constituent layer of the insulating resin layer exhibits a mean etching rate of 0.5 μm/min or more by a 50% aqueous solution of potassium hydroxide at 80° C., the layers in the insulating resin layer which exist in contact with the stainless steel substrate and the metal foil are those of polyimide (B) exhibiting a glass transition temperature of 300° C. or less, and the adhesive strength between the layer of polyimide (B) and either the stainless steel substrate or the metal foil is 0.5 kN/m or more.

2. An HDD suspension as described in claim 1 wherein the insulating resin layer of the laminate comprises at least one layer of low-thermal-expansion polyimide (A) exhibiting a coefficient of thermal expansion of 30×10^{-6/}° C. or less.

3. An HDD suspension as described in claim 1 wherein polyimide (B) constituting the insulating resin layer of the laminate is obtained by the reaction of a diamine and a tetracarboxylic acid dianhydride and 50 mol % or more of said tetracarboxylic acid dianhydride is one kind or two kinds of more of tetracarboxylic acid dianhydrides selected from pyromellitic dianhydride, 3,4,3′,4′-benzophenonetetracarboxylic acid dianhydride, 3,4,3′,4′-diphenylsulfonetetracarboxylic acid dianhydride and a tetracarboxylic acid dianhydride represented by the following general formula (1) 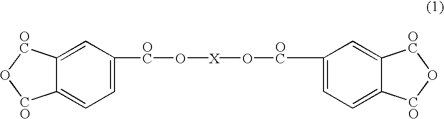
wherein X designates a linear or branched divalent aliphatic hydrocarbon group having 2-30 carbon atoms with or without substituents.

4. An HDD suspension as described in claim 1 wherein polyimide (B) constituting the insulating resin layer of the laminate is obtained by the reaction of a diamine and a tetracarboxylic acid dianhydride and 50 mol % or more of said diamine is one kind or more of diamines selected from 1,3-bis(3-aminophenoxy)benzene, 3,4′-diaminodiphenyl ether, a diamine represented by the following general formula (2) 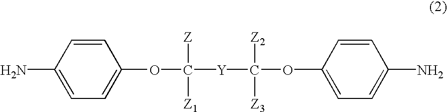
wherein Z, Z₁, Z₂ and Z₃ independently designate a hydrogen atom or an alkyl group with 1-3 carbon atoms and Y designates a linear or branched divalent aliphatic hydrocarbon group having 1-5 carbon atoms with or without substituents; and a diamine represented by the following general formula (3) 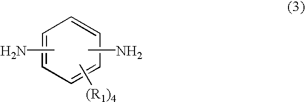
wherein R₁ designates independently hydrogen, an alkyl group with 1-10 carbon atoms, an alkoxy group with 1-10 carbon atoms or a halogen.

5. An HDD suspension as described in claim 1 wherein processing of the laminate comprises patterning of the insulating resin layer by wet etching as an essential step.

6. A process for manufacturing an HDD suspension which comprises utilizing a laminate constructed of an insulating resin layer and a metal foil successively formed on a stainless steel substrate and patterning the insulating resin layer of the laminate by wet etching as an essential step, said laminate satisfying the following conditions; the insulating resin layer has plural layers of polyimides and every constituent layer of the insulating resin layer exhibits a mean etching rate of 0.5 μm/min or more by a 50% aqueous solution of potassium hydroxide at 80° C., the layers in the insulating resin layer which exist in contact with the stainless steel substrate and the metal foil are those of polyimide (B) exhibiting a glass transition temperature of 300° C. or less, and the adhesive strength between the layer of polyimide (B) and either the stainless steel substrate or the metal foil is 0.5 kN/m or more.

7. A process for manufacting an HDD suspension as described in claim 6 wherein the patterning by wet etching is performed by the use of a basic fluid exhibiting a pH of 9 or more.

8. A process for manufacturing an HDD suspension as described in claim 6 wherein the patterning by wet etching is performed in 2-1,800 seconds.

9. A process for manufacturing an HDD suspension as described in claim 6 wherein the patterning of the insulating resin layer by wet etching is performed at 20-100° C. by the use of a basic fluid.
